(19) United States
(12) Patent Application Publication
(10) Pub. No.: US 2026/0250874 A1
(43) Pub. Date: Aug. 27, 2026

(54) PROCESSING APPARATUS AND CHIP MANUFACTURING METHOD

(71) Applicant: DISCO CORPORATION, Tokyo (JP)

(72) Inventors: Takahiro NAKAGAWA, Tokyo (JP); Hiroki ABE, Tokyo (JP)

(21) Appl. No.: 19/540,194

(22) Filed: Feb. 13, 2026

(30) Foreign Application Priority Data
Feb. 26, 2025 (JP) 2025-029567
Mar. 26, 2025 (JP) 2025-051443

(51) Int. Cl. C25D 7/12; B24B 7/22; H10P 72/00; H10P 72/30

(52) U.S. Cl. CPC C25D 7/123; B24B 7/228; H10P 72/0462; H10P 72/3314; H10P 72/3402

(57) ABSTRACT

A processing apparatus includes a first workpiece holder that holds a workpiece; a first stage drive that moves the first workpiece holder in a first direction which crosses a vertical direction; a second workpiece holder that is disposed to be adjacent to the first workpiece holder and holds a workpiece; a second stage drive that moves the second workpiece holder in the first direction; a first processing head that processes workpieces held by the first workpiece holder and the second workpiece holder; and a first elevating stage that moves the first processing head in the vertical direction, so as to move the first processing head to a first processing region in which workpieces held by the first workpiece holder and the second workpiece holder are processed.

### BACKGROUND OF THE DISCLOSURE

### 1. Field of the Disclosure

The present disclosure relates to a processing apparatus and a chip manufacturing method.

### 2. Description of the Related Art

A substrate, on the surface of which a plurality of devices, e.g. ICs, LSIs, are formed by being demarcated by division lines, is ground, polished and lathe-turned, and divided into individual chips by a dicing apparatus and a laser processing apparatus. These chips are used for electronic devices, such as mobile phones, personal computers, and electric equipment.

In a case of processing the above mentioned substrate, a procedure is required in which the substrate is loaded onto a processing apparatus, and is conveyed onto a holding surface of a holding unit, which holds the substrate during processing, and the substrate placed and held on the holding surface is then conveyed to a processing region where the substrate is processed, and after the substrate is processed, the substrate is positioned at a load/unload position and is unloaded from the holding unit. The procedure of load, convey and unload of the substrate takes time, and improvement of productivity is demanded.

As a processing apparatus that performs processing on a workpiece, a configuration is proposed where two holding tables that hold workpieces are provided, and each holding table includes two independent paths such that each of the holding tables moves in a predetermined direction, and a processing unit is provided to each of the two paths (see JP 2024-009560 A).

### SUMMARY OF THE DISCLOSURE

In a case of the above mentioned processing apparatus according to JP 2024-009560 A, a workpiece held on a first holding table can be processed only by a first processing unit, and a workpiece held on a second holding table can be processed only by a second processing unit, which means that productivity is low. Further, while a workpiece held on the first holding table is being processed by the first processing unit, a workpiece to be processed next by the first processing unit is not yet ready to be processed. In the same manner, while a workpiece held on the second holding table is being processed by the second processing unit, a workpiece to be processed next by the second processing unit is not yet ready to be processed. This means that not only is productivity low but also a large space is required to install such a processing apparatus, which does not conserve space. This problem also exists in a method for manufacturing chips by performing processing of dividing the surface of the workpiece.

With the foregoing in view, it is an object of the present disclosure to provide a processing apparatus and a chip manufacturing method which improve productivity and conserve installation space.

To solve the above technical problem, the present disclosure provides a processing apparatus, including: a first workpiece holder that holds a workpiece; a first stage drive that moves the first workpiece holder in a first direction which crosses a vertical direction; a second workpiece holder that is disposed to be adjacent to the first workpiece holder and holds a workpiece; a second stage drive that moves the second workpiece holder in the first direction; a first processing head that processes workpieces held by the first workpiece holder and the second workpiece holder; and a first elevating stage that moves the first processing head in the vertical direction, so as to move the first processing head to a first processing region in which workpieces held by the first workpiece holder and the second workpiece holder are processed. The first workpiece holder and the second workpiece holder are configured to be movable to the first processing region in the first direction, independently from each other.

It is preferable that the processing apparatus further includes: a second processing head that processes workpieces held by the first workpiece holder and the second workpiece holder; and a second elevating stage that moves the second processing head in the vertical direction, so as to move the second processing head to a second processing region in which the workpieces held by the first workpiece holder and the second workpiece holder are processed. It is also preferable that the processing apparatus further includes: a third workpiece holder that holds a workpiece; a third stage drive that moves the third workpiece holder in the first direction; a fourth workpiece holder that is disposed to be adjacent to the third workpiece holder and holds a workpiece; a fourth stage drive that moves the fourth workpiece holder in the first direction; a third processing head that is disposed aligned with the first processing head side-by-side, and processes workpieces held by the third workpiece holder and the fourth workpiece holder; and a third elevating stage that moves the third processing head in the vertical direction, so as to move the third processing head to a third processing region in which workpieces held by the third processing head and the fourth workpiece holder are processed. It is also preferable that the processing apparatus further includes: a fourth processing head that processes workpieces held by the third workpiece holder and the fourth workpiece holder; and a fourth elevating stage that moves the fourth processing head in the vertical direction, so as to move the fourth processing head to a fourth processing region in which workpieces held by the third workpiece holder and the fourth workpiece holder are processed.

It is preferable that the first workpiece holder and the second workpiece holder are disposed to be aligned vertically. It is also preferable that the first workpiece holder and the second workpiece holder are disposed to be aligned vertically, and the third workpiece holder and the fourth workpiece holder are disposed to be aligned vertically. Further, it is preferable that the processing apparatus includes: a first placing stage on which a workpiece is placed; and a first conveyor that includes a first conveying arm that holds a workpiece, and conveys the workpiece among the first placing stage, the first workpiece holder and the second workpiece holder.

It is preferable that the processing apparatus further includes: a second placing stage on which a workpiece is placed; and a second conveyor that includes a second conveying arm that holds a workpiece, and conveys the workpiece among the second placing stage, the first workpiece holder and the second workpiece holder. It is also preferable that the first conveying arm and the second conveying arm are disposed to be aligned vertically.

The present disclosure also provides a chip manufacturing method including: thinning a workpiece by using any of the processing apparatuses mentioned above; and dividing the workpiece after the thinning, so as to generate chips.

The processing apparatus of the present disclosure includes: a first workpiece holder that holds a workpiece; a first stage drive that moves the first workpiece holder in a direction which crosses a vertical direction; a second workpiece holder that is disposed to be adjacent to the first workpiece holder and holds a workpieces; a second stage drive that moves the second workpiece holder in the first direction; a first processing head that processes workpieces held by the first workpiece holder and the second workpiece holder; and a first elevating stage that moves the first processing head in the vertical direction, so as to move the first processing head to a first processing region in which workpieces held by the first workpiece holder and the second workpiece holder are processed. The first workpiece holder and the second workpiece holder are configured to be movable to the first processing region in the first direction, independently from each other. Therefore productivity improves and an installation space can be decreased.

The chip manufacturing method of the present disclosure includes: thinning a workpiece by using any of the processing apparatuses mentioned above; and dividing the workpiece after the thinning, so as to generate chips. Therefore productivity of the processing apparatus that performs the thinning is improved, and an installation space can be decreased. Further, productivity when chips are manufactured from the workpiece is improved, and an installation space of the apparatus required until chips are manufactured from the workpiece can be decreased.

### BRIEF DESCRIPTION OF THE DRAWINGS

FIG. 1. is a general perspective view of a processing apparatus of Embodiment 1;

FIG. 2 is a cross-sectional front view of a part of the processing apparatus in FIG. 1 which is partially enlarged;

FIG. 3 is a general perspective view of a processing apparatus of Embodiment 2;

FIG. 4 is a cross-sectional front view of a part of the processing apparatus in FIG. 3 which is partially enlarged;

FIG. 5 is a general perspective view of a processing apparatus of Embodiment 3;

FIG. 6 is a general perspective view of a processing apparatus of Embodiment 4; and

FIG. 7 is a general perspective view of a processing apparatus of Modifications.

### DESCRIPTION OF THE PREFERRED EMBODIMENTS

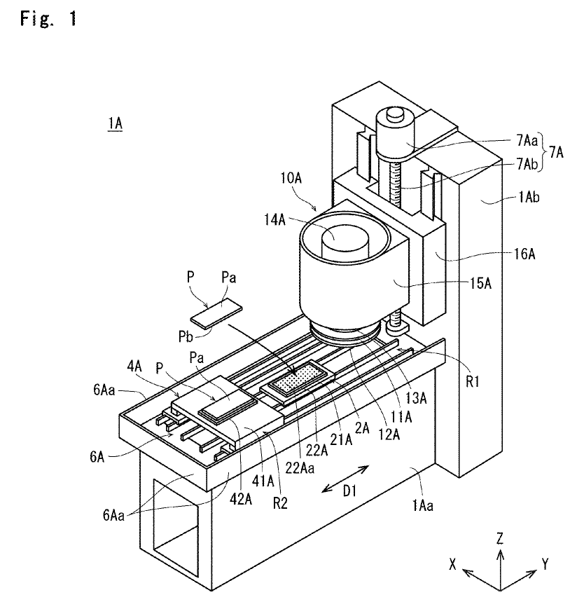

Embodiments of the processing apparatus configured based on the present disclosure, and embodiments of the chip manufacturing method implemented using the processing apparatus of the present disclosure will now be described with reference to the accompanying drawings. In the embodiment described below, a workpiece to be processed is a package substrate P, for example, where a plurality of devices are packaged on a rectangular substrate and the packaged devices are coated and sealed by a resin layer (molded resin) (see FIG. 1). Individual chips are manufactured by thinning the front face Pa of the package substrate P, and then forming division grooves by cutting along division lines which demarcate the plurality of devices. The present disclosure is applicable not only to processing the package substrate P mentioned above, but also to various plate members of which upper face side is processed. For example, the present disclosure is applicable to a processing apparatus that processes a circular plate-shaped semiconductor wafer on which front face a plurality of devices are formed demarcated by division lines, and to a method for manufacturing chips by dividing the semiconductor wafer.

### Embodiment 1

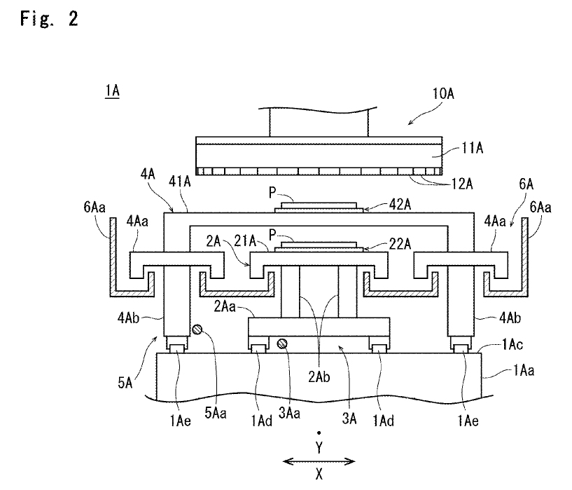

FIGS. 1 and 2 indicate a processing apparatus 1A of Embodiment 1, which processes the above mentioned package substrate P as a workpiece, and grinds the front face Pa of the package substrate P on which a resin layer is formed. This processing apparatus 1A includes: a first workpiece holder 2A that holds the package substrate P; a first stage drive 3A (see FIG. 2) that moves the first workpiece holder 2A in the first direction D1 along a direction (Y axis direction in FIGS. 1 and 2) crossing in a vertical direction (Z axis direction in FIG. 1); a second workpiece holder 4A that is disposed to adjacent to the first workpiece holder 2A, and holds the package substrate P; a second stage drive 5A (see FIG. 2) that moves the second workpiece holder 4A in the first direction D1; a first processing head 10A that processes the front faces Pa of the package substrates P held by the first workpiece holder 2A and the second workpiece holder 4A; and a first elevating stage 7A, that moves the first processing head 10A in the vertical direction, so as to move the first processing head 10A to a first processing region R1 in which the front faces Pa of the package substrates P held by the first workpiece holder 2A and the second workpiece holder 4A are processed. The first workpiece holder 2A and the second workpiece holder 4A are configured to be movable to the first processing region R1 in the above mentioned first direction D1, independently from each other. In Embodiment 1 described above, the first direction D1, crossing the above mentioned vertical direction (Z axis direction), is a direction along the Y axis direction, but the direction of the first direction D1, crossing the vertical direction, may be any direction along a plane defined by the X axis direction and the Y axis direction orthogonally intersecting with the vertical direction, and is not limited to the above mentioned Y axis direction.

The processing apparatus 1A illustrated in FIGS. 1 and 2 will be described more concretely. The processing apparatus 1A is a grinding apparatus that grinds the front face Pa of the package substrate P, and is installed on a base 1Aa. The first processing head 10A is a grinding unit that grinds the front face Pa of the package substrate P. As illustrated, the first processing head 10A includes: a grinding wheel 11A; a plurality of grinding stones 12A which are disposed annularly on the lower face of the grinding wheel 11A; a rotation shaft 13A which is rotatably held and includes the grinding wheel 11A at the lower end; an electric motor 14A which rotates the rotation shaft 13A; a support portion 15A which supports the first processing head 10A; and a moving base 16A which is supported by a front face on the front side of a vertical wall portion 1Ab, disposed on the rear side of the base 1Aa in the Y axis direction, so as to be elevated together with the support portion 15A, in the vertical direction (Z axis direction).

The first elevating stage 7A can move the first processing head 10A to an arbitrary position in the Z axis direction (vertical direction), for example, by converting the rotary motion of a pulse motor 7Aa to a linear motion via a ball screw 7Ab, which is rotated by this pulse motor 7Aa, transferring the linear motion to the moving base 16A. To the first processing region R1, in which the front face Pa of the package substrate P is processed by the grinding wheel 11A of the first processing head 10A, grinding water is supplied from a grinding water supply unit (not illustrated). The grinding water supply unit includes a communication passage which is connected to a grinding water supply source, and when grinding is performed, the grinding water supplied from this grinding water supply source is supplied to processing points of the grinding stones 12A which process the package substrates P held by chuck tables 22A and 42A. The grinding water supplied from the grinding water supply unit to the first processing region R1 flows through a drainage pan 6A surrounded by side walls 6Aa, and is drained from a drain port (not illustrated).

As illustrated in FIG. 1, the first workpiece holder 2A has a holding table 21A which includes a chuck table 22A to hold a rear face Pb of the package substrate P. A holding surface 22Aa of the chuck table 22A is constituted of a permeable member, and is connected to a suction source (not illustrated), so that a negative pressure is generated on the holding surface 22Aa by activating the suction source, and the package substrate P is suction-held thereby. In the same manner as the first workpiece holder 2A, the second workpiece holder 4A has a holding table 41A, which includes a chuck table 42A to hold the rear face Pb of the package substrate P, and just like the first workpiece holder 2A, a holding surface (not visible in FIG. 1) constituted of a permeable member is formed on the upper face of the chuck table 42A, and is connected to the suction source, so that a negative pressure is generated and the package substrate P is suction-held thereby.

As illustrated in FIGS. 1 and 2, the first workpiece holder 2A includes a moving base 2Aa, which moves along a pair of guide rails 1Ad and 1Ad which are disposed along the Y axis direction, near the center on the upper face 1Ac of the base 1Aa in the width direction (X axis direction). The lower face side of the holding table 21A of the first workpiece holder 2A is supported by a pair of support walls 2Ab and 2Ab which stand on the moving base 2Aa. The first stage drive 3A, which moves the first workpiece holder 2A in the first direction D1, can move the first workpiece holder 2A to an arbitrary position in the first direction D1 (Y axis direction), for example, by converting the rotary motion of a pulse motor (not illustrated) to linear motion via a ball screw 3Aa (FIG. 2 indicates only the cross section thereof), which is rotated by the pulse motor disposed along the first direction D1 (Y axis direction), and transferring the linear motion to the moving base 2Aa. Because of this configuration, the first workpiece holder 2A can hold a package substrate P loaded in the processing apparatus 1A and move the package substrate P between the load/unload region R2 (see FIG. 1,) where the package substate P is loaded or unloaded and the above mentioned first processing region R1.

As illustrated in FIGS. 1 and 2, the second workpiece holder 4A includes a pair of guide rails 1Ae and 1Ae which are disposed along the Y axis direction, on the outer side in the width direction (X axis direction), so as to sandwich the pair of guide rails 1Ad and 1Ad, on the upper face 1Ac of the base 1Aa. The second workpiece holder 4A also includes: a pair of moving bases 4Aa and 4Aa which move in the first direction D1 along the guide rails 1Ae and 1Ae; and a pair of support walls 4Ab and 4Ab which are disposed to support a lower face side of the moving bases 4Aa and 4Aa, and to slide on the pair of guide rails 1Ae and 1Ae. The second stage drive 5A, which moves the second workpiece holder 4A in the first direction D1 (Y axis direction), can move the second workpiece holder 4A supported by the pair of moving bases 4Aa to an arbitrary position in the first direction D1, for example, by converting the rotary motion of the pulse motor (not illustrated) to linear motion via a ball screw 5Aa (FIG. 2 indicates only the cross section thereof), which is rotated by the pulse motor disposed along the first direction D1, and transferring the linear motion to the moving base 4Aa. Because of this configuration, the second workpiece holder 4A can hold a package substrate P loaded in the processing apparatus 1A, and move the package substrate P between the load/unload region R2 and the above mentioned first processing region R1.

As illustrated in FIGS. 1 and 2, the first workpiece holder 2A and the second workpiece holder 4A are disposed aligned vertically. The chuck table 22A of the first workpiece holder 2A is configured to pass directly under the chuck table 42A of the second workpiece holder 4A in the first direction D1, and the chuck tables 22A and 42A can move between the first processing region R1 and the load/unload region R2, independently from each other.

Generally the processing apparatus 1A of Embodiment 1 has the above mentioned configuration. A procedure and functional effect of thinning a package substrate P by performing grinding using the illustrated processing apparatus 1A will be described.

When a package substrate P is processed using the processing apparatus 1A, an unprocessed package substrate P is conveyed to the processing apparatus 1A, and is placed such that the front face Pa faces up, on the chuck table 22A of the first workpiece holder 2A, which is positioned in the load/unload region R2. Then a negative pressure is generated and held on the holding surface 22Aa by activating the suction source (not illustrated), and a height of the front face Pa of the package substrate P is detected using a height detecting unit (not illustrated). Then the first processing head 10A is activated to rotate the grinding wheel 11A at a predetermined rotation speed, and the first elevating stage 7A is activated to set the height position of the grinding surface of the grinding stones 12A of the grinding wheel 11A at a height position to grind the package substrate P to a desired thickness. Then the first stage drive 3A is activated to move the chuck table 22A in the first direction D1 toward the first processing region R1, in which the grinding processing is performed using the grinding stones 12A, then creep feed grinding is performed to grind the front face Pa of the package substrate P. Here grinding water is supplied to processing points in the first processing region R1. If necessary, the grinding processing for the front face Pa of the package substrate P is performed for a plurality of times while adjusting the height of the first processing head 10A, so that the grinding processing is performed to thin the package substrate P until a desired finished thickness is implemented.

As mentioned above, the second workpiece holder 4A is positioned at the load/unload region R2 while the first processing head 10A is grinding the package substrate P held on the first workpiece holder 2A. Then an unprocessed package substrate P is placed on the chuck table 42A of the second workpiece holder 4A such that the front face Pa thereof faces up, and is suction-held by activating the suction source (not illustrated). Once the first processing head 10A completes the grinding processing on the package substrate P held on the first workpiece holder 2A, the first stage drive 3A is activated to move the first workpiece holder 2A to the load/unload region R2, and the second stage drive 5A is activated to move the second workpiece holder 4A to the first processing region R1. As mentioned above, the first workpiece holder 2A and the second workpiece holder 4A are disposed aligned vertically, and the first workpiece holder 2A and the second workpiece holder 4A are configured to be movable to the first processing region R1 in the first direction D1, independently from each other. Therefore the second workpiece holder 4A can be moved to the first processing region R1 simultaneously when the first workpiece holder 2A is moved to the load/unload region R2 after processing on the package substrate P held on the first workpiece holder 2A is completed.

In the case of grinding the package substrate P, held on the chuck table 42A of the second workpiece holder 4A, using the first processing head 10A, the height of the front face Pa of the package substrate P here is different from the height of the front face Pa of the package substrate P held on the first workpiece holder 2A, so the height position of the actual grinding is different from the height of the front face Pa. Otherwise the procedure is the same as that of the grinding of the package substrate P held by the first workpiece holder 2A described above.

While the first processing head 10A is grinding the package substrate P held by the second workpiece holder 4A, the first workpiece holder 2A is positioned in the load/unload region R2. Here such a cleaning unit as a cleaning water supply nozzle (not illustrated) may be disposed near the load/unload region R2, so as to clean the front face Pa of the processed package substrate P, which is positioned in the load/unload region R2. Then the negative pressure applied to the chuck table 22A of the first workpiece holder 2A is released, and the processed package substrate P is unloaded. Then an unprocessed package substrate P is placed on the chuck table 22A of the first workpiece holder 2A, and the suction source (not illustrated) is activated to suction-hold the package substrate P.

When the grinding of the package substrate P held on the second workpiece holder 4A is completed, the second stage drive 5A is activated to move the second workpiece holder 4A to the load/unload region R2, and the first stage drive 3A is also activated to move the first workpiece holder 2A to the first processing region R1. Then following the same procedure described above, the front face Pa of the package substrate P held by the first workpiece holder 2A is ground to a desired thickness. Thus the grinding of the package substrate P held on the first workpiece holder 2A and the grinding of the package substrate P held by the second workpiece holder 4A can be performed consecutively.

According to the configuration of the processing apparatus 1A of Embodiment 1 described above, the first workpiece holder 2A and the second workpiece holder 4A are disposed aligned vertically, and the first workpiece holder 2A and the second workpiece holder 4A can move to the first processing region R1 in the first direction D1, independently from each other, hence productivity is improved, and a space to install the processing apparatus 1A can be decreased.

In Embodiment 1 described above, the first processing head 10A is a grinding unit having the grinding wheel 11A, which includes a plurality of grinding stones 12A disposed annularly on the lower face side, but the present disclosure is not limited to this. The first processing head 10A may be a polishing unit which having a polishing wheel which includes a polishing pad on the lower face side, whereby the front face Pa of the package substrate P is polished. Further, the first processing head 10A may be a turning unit having a turning wheel which includes a turning tool with a blade made of single crystal diamond or the like on the tip, so that the turning processing is performed on the front face Pa of the package substrate P using the blade of the cutting tool.

### Embodiment 2

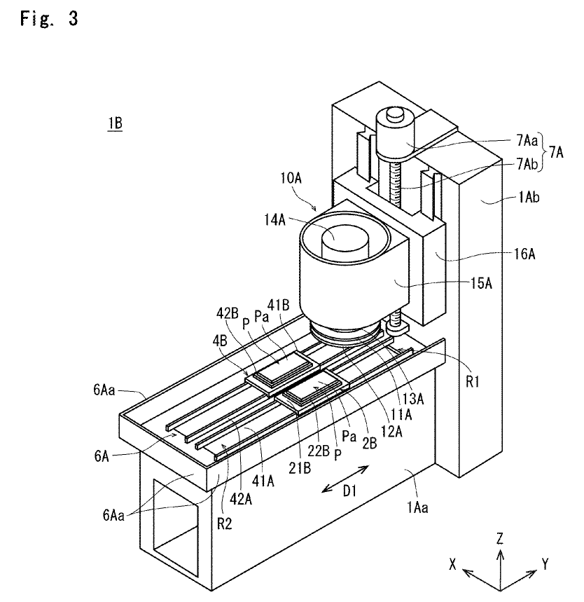

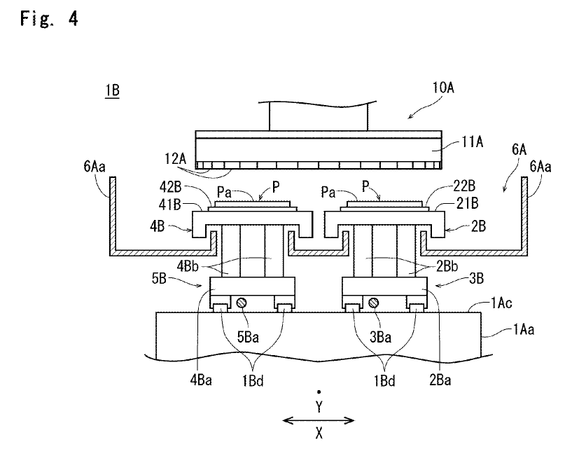

FIGS. 3 and 4 indicate a processing apparatus 1B of Embodiment 2, configured based on the present disclosure. The processing apparatus 1B includes: a first workpiece holder 2B that holds a package substrate P; a first stage drive 3B (see FIG. 4) that moves the first workpiece holder 2B in a first direction D1 along a direction (Y axis direction in FIGS. 3 and 4) crossing the first workpiece holder 2B in a vertical direction (Z axis direction in FIGS. 3 and 4); a second workpiece holder 4B that is disposed to adjacent to the first workpiece holder 2B and holds a package substrate P; and a second stage drive 5B (see FIG. 4) that moves the second workpiece holder 4B in the first direction D1. The processing apparatus 1B further includes: a first processing head 10A that processes front faces Pa of package substrates P held by the first workpiece holder 2B and the second workpiece holder 4B, and a first elevating stage 7A that moves the first processing head 10A in the vertical direction, so as to move the first processing head 10A to a first processing region R1, in which the front faces Pa of the package substrates P held by the first workpiece holder 2B and the second workpiece holder 4B are processed. The first workpiece holder 2B and the second workpiece holder 4B are configured to be movable to the first processing region R1 in the first direction D1, independently from each other. The processing apparatus 1B here has a same configuration as the above mentioned processing apparatus 1A of Embodiment 1, except for the first workpiece holder 2B and the first stage drive 3B, and the second workpiece holder 4B and the second stage drive 5B. For a composing element denoted with a same number as Embodiment 1, detailed description will be omitted.

The first workpiece holder 2B of Embodiment 2 has a holding table 21B which includes a chuck table 22B to hold a rear face Pb of the package substrate P. A holding surface (not visible in FIGS. 3 and 4) of the chuck table 22B is constituted of a permeable member, similar to that of the holding surface 22Aa of the chuck table 22A of Embodiment 1 described above, and is connected to a suction source (not illustrated), so that a negative pressure is generated on the holding surface by activating the suction source, and the package substrate P is suction-held thereby. In the same manner as the first workpiece holder 2B, the second workpiece holder 4B has a holding table 41B which includes a chuck table 42B to hold the rear face Pb of the package substrate P, and just like the first workpiece holder 2B, a holding surface (not visible in FIGS. 3 and 4), constituted of a permeable member, is formed on the upper face of the chuck table 42B, and is connected to the suction source, so that a negative pressure is generated, and the package substrate P is suction-held thereby.

As illustrated in FIG. 4, the first workpiece holder 2B includes a moving base 2Ba in addition to the above configuration, and the moving base 2Ba moves along a pair of guide rails 1Bd and 1Bd which are disposed along the Y axis direction (first direction D1) on the upper face 1Ac of the base 1Aa, at a position closer to the right side in the width direction (X axis direction). The lower face side of the holding table 21B of the first workpiece holder 2B is supported by a pair of support walls 2Bb and 2Bb which stand on the moving base 2Ba. The first stage drive 3B, which moves the first workpiece holder 2B in the first direction D1, can move the first workpiece holder 2B to an arbitrary position in the above mentioned first direction D1, for example, by converting the rotary motion of a pulse motor (not illustrated) to linear motion via a ball screw 3Ba disposed along the Y axis direction, and transferring the linear motion to the moving base 2Ba.

The second workpiece holder 4B of Embodiment 2 has a holding table 41B which includes a chuck table 42B to hold a rear face Pb of the package substrate P. A holding surface (not visible in FIGS. 3 and 4) of the chuck table 42B is constituted of a permeable member, just like the chuck table 22B of the first workpiece holder 2B described above, and is connected to a suction source (not illustrated), so that a negative pressure is generated on the holding surface by activating the suction source, and the package substrate P is suction-held thereby.

As illustrated in FIG. 4, the second workpiece holder 4B includes a moving base 4Ba in addition to the above configuration, and the moving base 4Ba moves along a pair of guide rails 1Be and 1Be which are disposed along the first direction D1 (Y axis direction) on the upper face 1Ac of the base 1Aa, at a position closer to the left side in the width direction (X axis direction). The lower face side of the holding table 41B of the second workpiece holder 4B is supported by a pair of support walls 4Bb and 4Bb which stand on the moving base 4Ba. The second stage drive 5B, which moves the second workpiece holder 4B in the first direction D1, can move the second workpiece holder 4B to an arbitrary position in the above mentioned first direction D1, for example, by converting rotary motion of a pulse motor (not illustrated) to linear motion via a ball screw 5Ba (only cross section is illustrated in FIG. 4) disposed along the first direction D1 (Y direction) in which the ball screw 5Ba is rotated by the pulse motor, and transferring the liner motion to the moving base 4Ba.

As illustrated in FIGS. 3 and 4, the chuck table 22B of the first workpiece holder 2B and the chuck table 42B of the second workpiece holder 4B are disposed to adjacent to each other in the X axis direction, such that the heights of the holding surfaces thereof match on a same plane. The first workpiece holder 2B and the second workpiece holder 4B are configured to be movable to the first processing region R1 in the first direction D1, independently from each other.

In Embodiment 2 as well, the grinding processing can be performed in the same procedure as Embodiment 1 described above. In other words, a package substrate P held on a first workpiece holder (one of the first workpiece holder 2B and the second workpiece holder 4B) is positioned in the first processing region R1, and this package substrate P is ground by the first processing head 10A. During this grinding processing, a second workpiece holder (the other one of the first workpiece holder 2B and the second workpiece holder 4B) is positioned in the load/unload region R2 illustrated in FIG. 3, and an unprocessed package substrate P is placed and suction-held on the chuck table of the second workpiece holder. Then after the package substrate P held on the chuck table on the first workpiece holder is ground, this package substrate P, along with the first workpiece holder, is moved to the load/unload region R2. At the same time, the second holding table where the unprocessed package substrate P is suction-held is moved to the first processing region R1, where the first processing head 10A performs grinding processing. Parallel with this grinding processing, the negative pressure applied to the chuck table of the first holding table is released, the processed package substrate P is unloaded, and the unprocessed package substrate P is placed on the chuck table of the first holding table, then the suction source (not illustrated) is activated to suction-hold the unprocessed package substrate P. Once the grinding processing on the package substrate P held on the second workpiece holder is completed, the second workpiece holder is moved to the load/unload region R2, and parallel with this movement, the first workpiece holder on which the unpressed package substrate P is held is moved to the first processing region R1, where the front face Pa of the package substrates P is ground by the procedure similar to the above mentioned procedure. By the consecutive grinding processing on the package substrate P like this, a functional effect similar to Embodiment 1 described above can be implemented.

In Embodiment 2 illustrated in FIGS. 3 and 4, the first workpiece holder 2B and the second workpiece holder 4B are disposed aligned side-by-side in the horizontal direction, such that the width of the two package substrates P placed on the two adjacent chuck tables is within a diameter of the grinding wheel 11A of the first processing head 10A. Thereby the two package substrates P, which are placed and held by the first workpiece holder 2B and the second workpiece holder 4B may be ground simultaneously by the first processing head 10A.

### Embodiment 3

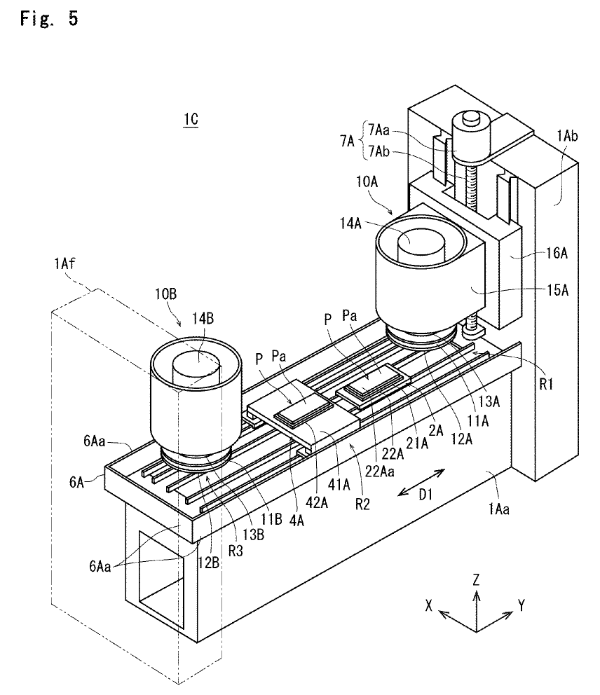

FIG. 5 indicates a processing apparatus 1C of Embodiment 3, configured based on the present disclosure. In addition to the above mentioned configuration of the processing apparatus 1A of Embodiment 1, the processing apparatus 1C includes a second processing head 10B that processes front faces Pa of package substrates P held by the first workpiece holder 2A and the second workpiece holder 4A in a second processing region R3, which is on the opposite side of the first processing region R1 in the first direction D1 (Y axis direction). The first workpiece holder 2A and the second workpiece holder 4A are configured to be movable in the first direction D1, to the first processing region R1 and the second processing region R3, independently from each other, and can process the front faces Pa of the package substrates P held by the first workpiece holder 2A and the second workpiece holder 4A in the first processing region R1 and the second processing region R3. In this configuration, the load/unload region R2 is set at a center between the first processing region R1 and the second processing region R3 in the first direction D1.

The second processing head 10B is elevatedly supported by a vertical wall portion 1Af, which is indicated by a two-dot chain line in FIG. 5 on the front side in the Y axis direction. A second elevating stage (omitted in FIG. 5 for explanatory convenience) is disposed in the vertical wall portion 1Af, and the second elevating stage has a configuration similar to the first elevating stage 7A described with reference to FIG. 1, and includes a support portion and a moving base which have a configuration similar to the support portion 15A and the moving base 16A illustrated in FIG. 1. Therefore the second processing head 10B is movable in the vertical direction (Z axis direction) using the second elevating stage, whereby the package substrates P held by the first workpiece holder 2A and the second workpiece holder 4A can be processed in the second processing region R3. The processing apparatus 1C has a configuration similar to the processing apparatus 1A of Embodiment 1, except that the configuration of the second processing head 10B and the vertical wall portion 1Af is different. For a composing element denoted by a same reference number in Embodiment 1, detailed description will be omitted.

For the second processing head 10B in the processing apparatus 1C of Embodiment 3, a processing head similar to the above mentioned first processing head 10A can be selected, which includes, for example: a grinding wheel 11B; a plurality of grinding stones 12B which are disposed annularly on the lower face of the grinding wheel 11B; a rotation shaft 13B which is rotatably held, and includes the grinding wheel 11B at the lower end; and an electric motor 14B which rotates the rotation shaft 13B. The second processing head 10B can perform grinding processing similar to the first processing head 10A.

According to the processing apparatus 1C described above, the package substrates P, which are suction-held by the first workpiece holder 2A and the second workpiece holder 4A, can be simultaneously ground in the first processing region R1 and the second processing region R3 respectively. In other words, by adjusting the timings to execute the grinding processing in the first processing region R1 and the second processing region R3, the timings to load, place and suction-hold the unprocessed package substrates P in the load/unload region R2, the timings to unload the processed package substrates P, and the like, and load and unload of the package substrates P in the first workpiece holder 2A and the second workpiece holder 4A, can be performed consecutively, and the grinding of the package substrates P suction-held by the first workpiece holder 2A and the second workpiece holder 4A can also be performed consecutively in parallel. Hence compared with the processing apparatus 1A of Embodiment 1 described above, productivity is improved even more. Further, compared with the case of installing two processing apparatuses as described in the above mentioned JP 2024-009560 A, installation space can be dramatically conserved.

In the processing apparatus 1C of Embodiment 3 described above, the first processing head 10A and the second processing head 10B include the same grinding stones respectively, but the present disclosure is not limited to this. For example, the grinding stones 12A of the first processing head 10A may be constituted of grinding stones which roughly grind the front face Pa of the package substrate P, and the grinding stones 12B of the second processing head 10B may be constituted of fine grinding stones for finish-grinding, so that the package substrate P which was roughly ground by the first processing head 10A in the first processing region R1 is directly moved to the second processing region R3 along the first processing direction D1, where finish-grinding is performed by the second processing head 10B. Further, a grinding unit may be selected as the first processing head 10A and a polishing unit may be selected as the second processing head 10B, so that grinding processing is performed on the package substrate P in the first processing region R1 and then this package substrate P is moved to the second processing region R3, where the polishing processing is performed on the package substrate P.

Furthermore, in the example of Embodiment 3 described above, the second processing head 10B is added to the above mentioned processing apparatus 1A of Embodiment 1, but the present disclosure is not limited to this, and the processing apparatus may include the above mentioned second processing head 10B in addition to the processing apparatus 1B of Embodiment 2 described above. In this case as well, a functional effect similar to Embodiment 3 described above can be implemented.

### Embodiment 4

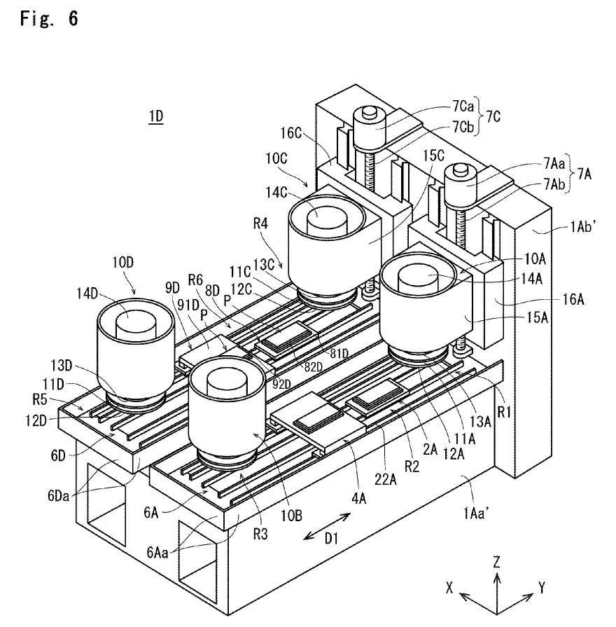

FIG. 6 is a processing apparatus 1D of Embodiment 4 configured based on the present disclosure. The processing apparatus 1D of Embodiment 4 at least includes, in addition to the above mentioned configuration of the processing apparatus 1C of Embodiment 3: a third workpiece holder 8D that holds a package substrate P (workpiece); a third stage drive (not illustrated) that moves the third workpiece holder 8D in the first direction D1; a fourth workpiece holder 9D that is disposed to adjacent to the third workpiece holder 8D and holds a package substrate P; a fourth stage drive (not illustrated) that moves the fourth workpiece holder 9D in the first direction D1; a third processing head 10C that is disposed aligned side-by-side with the first processing head 10A, and processes the package substrates P held by the third workpiece holder 8D and the fourth workpiece holder 9D; and a third elevating stage 7C that moves the third processing head 10C in the vertical direction, to the third processing region R4, in which the package substrates P held by the third workpiece holder 8D and the fourth workpiece holder 9D are processed. In FIG. 6, the vertical wall portion that elevatably supports the second processing head 10B is omitted for explanatory convenience.

The third processing head 10C is a grinding unit, for example, that grinds the front face Pa of the package substrate P. As illustrated, the third processing head 10C includes: a grinding wheel 11C; a plurality of grinding stones 12C which are disposed annularly on the lower face of the grinding wheel 11C; a rotation shat 13C which is rotatably held and includes the grinding wheel 11C at the lower end; an electric motor 14C which rotates the rotation shaft 13C; a support portion 15C which supports the third processing head 10C; and a moving base 16C which is supported by a side face on a front side of a vertical wall portion 1Ab’, disposed on the rear side of the base 1Aa’ in the Y axis direction, so as to be elevatable together with a support portion 15C in the vertical direction (Z axis direction).

The third workpiece holder 8D and the fourth workpiece holder 9D may have configurations similar to the first workpiece holder 2A and the second workpiece holder 4A described with reference to FIGS. 1 and 2, for example. The third stage drive that moves the third unit 8D in the first direction D1 and the fourth stage drive that moves the fourth workpiece holder 9D in the first direction D1 can have configurations similar to the first stage drive 3A and the second stage drive 5A described above with reference to FIG. 2, hence detailed description is omitted here.

The processing apparatus 1D illustrated in FIG. 6 is disposed on a base 1Aa’ that is formed wider than the above mentioned base 1Aa, and includes all the configurations indicated in Embodiment 3 described above, and also includes the vertical wall portion 1Ab’, which is disposed on the rear side of the base 1Aa’ in the Y axis direction, and which elevatably supports the first processing head 10A and the third processing head 10C. The third elevating stage 7C elevates the third processing head 10C above the third processing region R4 where the package substrate P is processed by the third processing head 10C. The third elevating stage 7C is disposed in the vertical wall portion 1Ab’, aligned side-by-side with the first elevating stage 7A, and is configured such that the rotary motion of a pulse motor 7Ca is converted to linear motion via a ball screw 7Cb which is rotated by the pulse motor 7Ca, and the linear motion is transferred to the moving base 16C. The grinding wheel 11C of the third processing head 10C can be moved to an arbitrary portion in the Z axis direction (vertical direction), specifically to the third processing region R4.

The processing apparatus 1D of Embodiment 4 illustrated in FIG. 6 is an example that includes, in addition to the configuration of the processing apparatus 1C of Embodiment 3: a third workpiece holder 8D; a third stage drive; a fourth workpiece holder 9D; a fourth stage drive; a third processing head 10C; and the third elevating stage 7C. The first workpiece holder 1A and the second workpiece holder 4A are disposed aligned vertically, and the third workpiece holder 8D and the fourth workpiece holder 9D are also disposed aligned vertically. However, the present disclosure is not limited to this, and for example, the above mentioned configuration of the third workpiece holder 8D, the third stage drive, the fourth workpiece holder 9D, the fourth stage drive, the third processing head 10C, and the third elevating stage 7C may be added to the configuration of the processing apparatus 1A of Embodiment 1 described with reference to FIGS. 1 and 2, or to the configuration of the processing apparatus 1B of Embodiment 2 described with reference to FIGS. 3 and 4. Further, the third workpiece holder 8D and the fourth workpiece holder 9D may be configured to be disposed to be adjacent to each other in parallel at the same height, as in the case of the first workpiece holder 2B and the second workpiece holder 4B described with reference to FIGS. 3 and 4.

The third processing head 10C may be a processing unit similar to the first processing head 10A or the second processing head 10B described above, but may be a processing head that is different from the first processing head 10A and the second processing head 10B. For example, a grinding unit that performs grinding processing on the package substrate P may be selected for the first processing head 10A and the second processing head 10B, and either a polishing unit or a turning unit may be selected for the third processing head 10C. Furthermore, all the three processing heads may be different processing heads. For example, a rough grinding unit which performs rough grinding may be selected for the first processing head 10A, a finish grinding unit which performs finish grinding may be selected for the second processing head 10B, and a final finish grinding unit which performs final finish grinding (using even finer grinding stones than the second processing head 10B) may be selected for the third processing head 10C, and the grinding processing by each unit may be performed in parallel.

In Embodiment 4 described above, the third workpiece holder 8D, the third stage drive, the fourth workpiece holder 9D, the fourth stage drive, the third processing head 10C, and the third elevating stage 7C are included in addition to a configuration of one of Embodiments 1 to 3. Hence not only the functional effects obtained by one of Embodiments 1 to 3, but also productivity can be further improved, and installation space can be further conserved due to the added configuration.

### Embodiment 5

The processing apparatus 1D illustrated in FIG. 6 also includes Embodiment 5, which includes, in addition to the configuration implemented by Embodiment 4 described above: a fourth processing head 10D that processes package substrates P held by the third workpiece holder 8D and the fourth workpiece holder 9D in a fourth processing region R5; and a fourth elevating stage (not illustrated) that moves the fourth processing head 10D vertically to the fourth processing region R5.

The fourth processing head 10D may be selected from the first processing head 10A, the second processing head 10B, and the third processing head 10C described above. The fourth processing head 10D illustrated in FIG. 6 is a grinding unit, for example, which grinds the front face Pa of a package substrate P. As illustrated, the fourth processing head 10D includes: a grinding wheel 11D, a plurality of grinding stones 12D that are disposed annularly on the lower face of the grinding wheel 11D; and an electric motor 14D that rotates a rotation shaft 13D which is rotatably held and includes the grinding wheel 11D at the lower end. The illustrated example includes a fourth elevating stage (not illustrated) that elevates the fourth processing head 10D on a vertical wall portion (not illustrated) that elevatably supports the fourth processing head 10D. The vertical wall portion includes a support portion (not illustrated) which supports the fourth processing head 10D, and a moving base that is supported to be elevatable along with the support portion, in the vertical direction (Z axis direction). In FIG. 6, a vertical wall portion on the front side, which elevatably supports the second processing head 10B and the fourth processing head 10D, is omitted for explanatory convenience, but this vertical wall portion has the same configuration as the vertical wall portion 1Ab’ which elevatably supports the first processing head 10A and the

third processing head 10C in the processing apparatus 1D illustrated in FIG. 6, and the second elevating stage and the fourth elevating stage have the same configurations as the first elevating stage 7A and the third elevating stage 7C described above. Due to the functions of the third stage drive and the fourth stage drive described above, the third workpiece holder 8D and the fourth workpiece holder 9D can be moved among the third processing region R4 which is set on the rear side in the Y axis direction, the fourth processing region R5 which is set on the front side in the Y axis direction, and the load/unload region R6 which is set at the center between the third processing region R4 and the fourth processing region R5.

As described above, Embodiment 5 is configured to include the configuration implemented in Embodiment 4, hence functional effects similar to Embodiment 4 can be obtained. In addition, a package substrate P can also be efficiently processed by the fourth processing head 10D. In Embodiment 5 as well, various combinations of processing heads can be selected for the first to fourth processing heads. For example, a rough grinding unit which performs rough grinding may be selected for the first processing head 10A, a finish grinding unit which performs finish grinding may be selected for the second processing head 10B, a rough grinding unit which performs rough grinding may be selected for the third processing head 10C, and a finish grinding unit which performs finish grinding may be selected for the fourth processing head 10D. The grinding processing for the package substrate P by each head may be performed in parallel. If the same processing head (e.g. rough grinding unit) is selected for all first to fourth processing heads, the same processing can be efficiently performed on a plurality of package substrates P. This further improves productivity, and installation space can be further decreased compared with conventional processing apparatuses which perform similar processing.

### Modifications

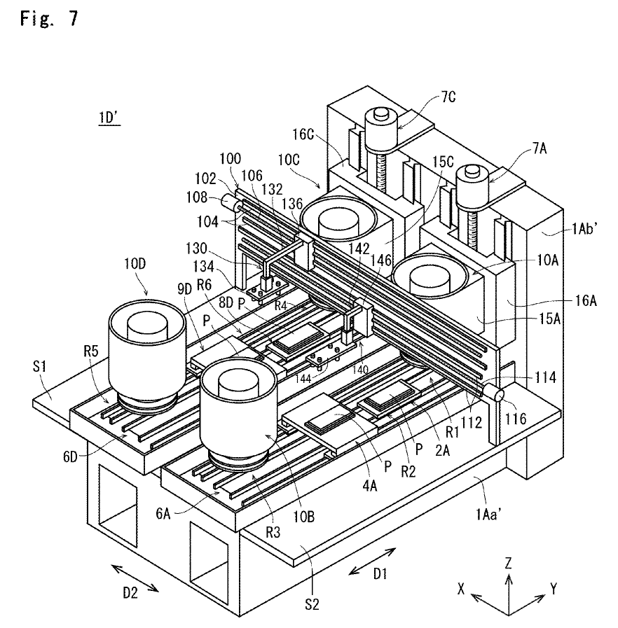

The above mentioned Embodiments 1 to 5 configured based on the present disclosure may be modified to include an additional configuration which will be described with reference to FIG. 7. A processing apparatus 1D’ of the modification described below is a case where the processing apparatus 1D of Embodiment 5 includes an additional configuration, and includes at least: a first placing stage S1 on which a package substrate P is placed; and a first conveyor 130 that conveys a workpiece among the first placing stage S1, the first workpiece holder 2A, and the second workpiece holder 4A.

The first placing stage S1 is disposed on the side of the processing apparatus 1D’ illustrated in FIG. 7. The first placing stage S1 is a table type shelf, for example, on which an unprocessed package substrate P or a processed package substrate P can be placed. On the first placing stage S1, a magazine (not illustrated) to house an unprocessed package substrate P and a magazine to house a processed package substrate P, may be placed, and a load/unload mechanism (not illustrated), to unload an unprocessed package substrate P from the magazine, or to load a processed package substrate P, may be disposed.

A first conveying arm 132 of the first conveyor 130 includes a suction pad 134 at the lower end. A plurality of suction portions are formed on the suction pad 134. The suction pad 134 is connected to a suction source (not illustrated), so that negative pressure can be generated. The suction pad 134 is elevatably configured with respect to the first conveying arm 132, by a driving unit (not illustrated), such as a driving unit constituted of a ball screw, a pulse motor, and guide rails, or a driving unit constituted of an air cylinder.

The processing apparatus 1D’ includes a gate-shaped column 100 which extends over a moving path (first direction D1) of each holding table in the X axis direction. On the side face 102 of the column 100, a pair of guide rails 104 and 104 are disposed to be along a second direction D2 (along X axis direction). The first conveying arm 132 is connected to a moving base 136. The moving base 136 slidably engages with the pair of guide rails 104 and 104, and can move in the second direction D2 (X axis direction) along the pair of guide rails 104 and 104. The first conveyor 130 includes a moving mechanism that includes: a ball screw 106 which is disposed between the pair of guide rails 104 and 104, and extends in the X axis direction; and a pulse motor 108 that rotates the ball screw 106. The moving base 136 includes a nut portion (not illustrated) in which the ball screw 106 is screwed. By converting the rotary motion of the ball screw 106, which is rotated by the pulse motor 108, to the linear motion, and transferring the linear motion to the moving base 136, the first conveying arm 132 can be moved to an arbitrary position in the second direction D2, and the suction pad 134 of the first conveying arm 132 is positioned above the load/unload region R2, which is set between the first processing region R1 and the second processing region R3, and the load/unload region R6, which is set at the center between the second processing region R4 and the fourth processing region R5.

According to the above mentioned configuration, the first conveyor 130 can be moved above the first placing stage S1, along the pair of guide rails 104 and 104. The first conveyor 130 can also lower the suction pad 134 of the first conveying arm 132 to an unpressed package substrate P placed on the first placing stage S1 and suction-hold the unprocessed package substrate P. Once the unprocessed package substrate P is suction-held, the first conveyor 130 can raise the suction pad 134 and activate the above mentioned pulse motor 108, so that the first conveying arm 132 moves in the second direction D2 and the package substrate P is positioned above the load/unload region R2. The unprocessed package substrate P can be placed on one of the first workpiece holder 2A and the second workpiece holder 4A positioned in the load/unload region R2, and be suction-held. Further, a package substrate P, processed by the first processing head 10A or the second processing head 10B, can also be unloaded by the first conveying arm 132 from the first workpiece holder 2A or the second workpiece holder 4A positioned in the load/unload region R2, and conveyed to and placed in the first placing stage S1. In other words, because the first conveyor 130 is included, the package substrate P can be conveyed among the first placing stage S1, the first workpiece holder 2A, and the second workpiece holder 4A.

The modification illustrated in FIG. 7 further includes, in addition to the above configuration: the second placing stage S2 on which package substrate P is placed; and the second conveyor 140 that includes the second conveying arm 142 to hold the package substrate P, and conveys the package substrate P among the second placing stage S2, the first workpiece holder 2A, and the second workpiece holder 4A.

The second placing stage S2 is disposed on the front side of the processing apparatus 1D’ illustrated in FIG. 7, which is on the opposite side to the above mentioned first placing stage S1 in the second direction D2 (X axis direction). The second placing stage S2 is a table-shaped shelf, just like the first placing stage S1, on which an unprocessed package substrate P or a processed package substrate P can be placed. On the second placing stage S2, a magazine (not illustrated) to house an unprocessed package substrate P and a magazine to house a processed package substrate P, may be placed, and a load/unload mechanism (not illustrated), to load/unload an unprocessed package substrate P and a processed package substrate P to/from the magazine, may be disposed.

A second conveying arm 142 of the second conveyor 140 includes a suction pad 144 at the lower end. A plurality of suction portions are formed on the lower face side of the suction pad 144. The suction pad 144 is connected to a suction source (not illustrated) so that negative pressure can be generated. The suction pad 144 is elevatably configured with respect to the second conveying arm 142, by an air cylinder, or the like (not illustrated).

On the side face 102 of the above mentioned gate-shaped column 100, a pair of guide rails 112 and 112 are disposed, so as to be parallel with the pair of guide rails 104 and 104 along the X axis direction. The second conveying arm 142 is connected to a moving base 146. The moving base 146 is slidably engaged with the pair of guide rails 112 and 112, and can move in the second direction D2 along the pair of guide rails 112 and 112. The second conveyor 140 is disposed between the pair of guide rails 112 and 112, and includes a ball screw 114 which extends in the X axis direction, and a pulse motor 116 which rotates the ball screw 114. The moving base 146 includes a nut portion (not illustrated) in which the ball screw 114 is screwed. By converting the rotary motion of the ball screw 114, which is rotated by the pulse motor 116, to the linear motion and transferring the linear motion to the moving base 146, the second conveying arm 142 can be moved to an arbitrary position in the second direction D2, along the pair of guide rails 112 112.

According to the above mentioned configuration, the second conveying arm 142 of the second conveyor 140 is moved above the second placing stage S2, along the pair of guide rails 112 and 112. The second conveyor 140 can also lower the suction pad 144 of the second conveying arm 142 to a package substrate P placed on the second placing stage S2, and suction-hold the package substrate P. Once the package substrate P is suction-held on the second placing stage S2 by the second conveying arm 142, the second conveyor 140 can raise the suction pad 144, and activate the above mentioned pulse motor 116, so that the second conveying arm 142 moves in the second direction D2 and the unprocessed package substrate P is positioned above the first workpiece holder 2A, and the second workpiece holder 4A which is positioned in the load/unload region R2. The package substrate P can be lowered, so as to be placed and suction-held on the first workpiece holder 2A or the second workpiece holder 4A. Further, a package substrate P processed by the first processing head 10A or the second processing head 10B, can also be unloaded by the second conveying arm 142 from the first workpiece holder 2A or the second workpiece holder 4A positioned in the load/unload region R2, and conveyed to and placed in the second placing stage S2. In other words, because the second conveyor 140 is included, the package substrate P can be conveyed among the second placing stage S2, the first workpiece holder 2A, and the second workpiece holder 4A.

As described above, in the modification illustrated in FIG. 7, the first conveyor 130 and the second conveyor 140 are included, hence package substrates P can be processed in various ways. For example, the first conveyor 130 is activated and an unprocessed package substrate P is unloaded from the first placing stage S1, is then conveyed to and placed on the first workpiece holder 2A or the second workpiece holder 4A positioned in the load/unload region R2, and is suction-held thereby. Then the front face Pa of the package substrate P is processed by one or both of the first processing head 10A and the second processing head 10B. Then the package substrate P, processed by the first processing head 10A and/or the second processing head 10B, is positioned in the load/unload region R2 by the first workpiece holder 2A or the second workpiece holder 4A, unloaded by the second conveyor 140, and conveyed to the second placing stage S2.

In other words, the first conveyor 130 may be used mainly as a unit to unload an unprocessed package substate P from the first placing stage S1 and to convey it to the load/unload region R2, and the second conveyor 140 may be used mainly as a unit to unload a processed package substrate P from the load/unload region R2 and to convey it to the second placing stage S2. Thereby while the first conveyor 130 is moving among the first placing stage S1, the first workpiece holder 2A, and the second workpiece holder 4A, the second conveyor 140 can be activated so as to unload the processed package substrate P from the first workpiece holder 2A or the second workpiece holder 4A, and convey the package substrate P to the second placing stage S2.

The present modification is not limited to the embodiment described above. For example, the first conveyor 130 may be set to convey an unprocessed package substrate P and a processed package substrate P among the first placing stage S1, the first workpiece holder 2A, and the second workpiece holder 4A, so that the second conveyor 140 can also convey an unprocessed package substrate P and a processed package substrate P among the second placing stage S2, the first workpiece holder 2A, and the second workpiece holder 4A.

As illustrated in FIG. 7, the first conveying arm 132 and the second conveying arm 142 are configured to pass not only the first workpiece holder 2A and the second workpiece holder 4A, but also above the load/unload region R5 of the third workpiece holder 8D and the fourth workpiece holder 9D. In other words, the conveying arm 132 of the first conveyor 130 can convey the package substrate P among the first placing stage S1, the third workpiece holder 8D, and the fourth workpiece holder 9D as well. The conveying arm 142 of the second conveyor 140 is also configured to pass above the load/unload region R5 of the third workpiece holder 8D and the fourth workpiece holder 9D. In other words, the second conveyor 140 can convey the package substrate P among the second placing stage S2, the third workpiece holder 8D, and the fourth workpiece holder 9D. Therefore the first conveyor 130 can convey a package substrate P among the first placing stage S1, the first workpiece holder 2A, the second workpiece holder 4A, the third workpiece holder 8D, and the fourth workpiece holder 9D, and the second conveyor 140 can convey a package substrate P among the second placing stage S2, the first workpiece holder 2A, the second workpiece holder 4A, the third workpiece holder 8D, and the fourth workpiece holder 9D.

Further, the first conveying arm 132 of the first conveyor 130 may be configured to be movable onto the second placing stage S2, so that the first conveying arm 132 can convey a package substrate P among the first placing stage S1, the first workpiece holder 2A, the second workpiece holder 4A, the third workpiece holder 8D, the fourth workpiece holder 9D, and the second placing stage S2. In the same manner, the second conveying arm 142 of the second conveyor 140 may be configured to be movable onto the first placing stage S1, so that the second conveying arm 142 can convey a package substrate P among the first placing stage S1, the first workpiece holder 2A, the second workpiece holder 4A, the third workpiece holder 8D, the fourth workpiece holder 9D, and the second placing stage S2.

In the modification illustrated in FIG. 7, the first conveying arm 132 and the second conveying arm 142 are disposed aligned vertically. In other words, when the first conveying arm 132 and the second conveying arm 142 are viewed from the side of the processing apparatus 1D’, the first conveying arm 132 and the second conveying arm 142 are disposed aligned vertically. Specifically, with regard to the suction pad 134 of the first conveying arm 132 and the suction pad 144 of the second conveying arm 142, at any timing of the conveying processing, the suction pad 134 of the first conveying arm 132 and the suction pad 144 of the second conveying arm 142 at least partially overlap vertically, and the suction pad 134 of the first conveying arm 132 and the suction pad 144 of the second conveying arm 142 vertically cross each other in the second direction D2 (X axis direction). By this configuration, installation space can be conserved even if the first conveying arm 132 and the second conveying arm 142 are disposed. For example, while the first conveying arm 132 is conveying a package substrate P from the first placing stage S1 to the first workpiece holder 2A of the load/unload region R2, the second conveying arm 142 can convey a package substrate P from the third workpiece holder 8D positioned in the load/unload region R6 to the second placing stage S2.

In the processing apparatus 1D’ of the modification illustrated in FIG. 7, the first conveyor 130 and the second conveyor 140 are additionally disposed to the processing apparatus 1D described with reference to FIG. 6, but the present disclosure is not limited to this. The present disclosure includes, for example, the processing apparatus 1A of Embodiment 1, an embodiment where only the first conveyor 130 is disposed in the processing apparatus 1B of Embodiment 2 described with reference to FIGS. 3 and 4, or in the processing apparatus 1C of Embodiment 3 described with refence to FIG. 5, and also includes an embodiment where not only the first conveyor 130 but also the second conveyor 140 are disposed in Embodiments 1 to 3.

Further, in the modification described above, when the first conveyor 130 and the second conveyor 140 are disposed in the processing apparatus of each embodiment, a pair of guide rails, corresponding to the first conveyor 130 and the second conveyor 140, are disposed on the side face 102 of the gate-shaped column 100, and each conveyor is moved along this pair of guide rails, but the present disclosure is not limited to this. For example, on the side face 102 of the gate-shaped column 100, only the first conveyor 130, which moves along the pair of guide rails 104 and 104, may be disposed, and on the side face on the opposite side (rear face side) of this side face 102, a pair of guide rails 112 and 112 may be formed along the same direction as the pair of guide rails 104 and 104, and the second conveyor 140, which moves along this pair of guide rails 112 and 112, may be disposed. Further, only the first conveyor 130 may be disposed on the gate-shaped column 100, and a separate new gate-shaped column (may have the same shape as the above mentioned gate-shaped column 100) may be disposed in parallel with the gate-shaped column 100, and a pair of guide rails 112 and 112 may be formed along the X axis direction on the side face of the new gate-shaped column, so that the second conveyor 140 is disposed to move on this pair of guide rails 112 and 112. In this case, the second conveyor 140 may move at a position facing the first conveyor 130, or the second conveyor 140 may move on the rear face side of the first conveyor 130. Further, in the new gate-shaped column, a pair of guide rails 112 and 112 may be disposed on the side face facing the same direction as the side face 102 of the above mentioned gate-shaped column 100, so that the second conveyor 140 is moved at the position facing the same direction as the first conveyor 130. Even in a case where the new gate-shaped column is disposed in addition to the gate-shaped column 100 as described above, so as to dispose and move the second conveyor 140, the first conveying arm 132 and the second conveying arm 142 can be configured to be aligned vertically, by appropriately setting the shape of the second conveying arm 142. In this way installation space can be effective conserved.

In each embodiment described above, the first to fourth stage drives, the first to fourth elevating stages, and the mechanism to move the first conveyor 130, the second conveyor 140, and the like in the second direction D2, are configured by a driving mechanism, including the pulse motor and the ball screw, but the present disclosure is not limited to this, and the moving and elevating operations may be implemented using other known driving mechanisms. For example, instead of the driving mechanism that includes the pulse motor and the ball screw described above, a linear motor actuator may be used, or a rack and pinion mechanism may be used.

By using the above mentioned processing apparatuses 1A to 1D’, the chip manufacturing method based on the present disclosure can be implemented. An embodiment according to the chip manufacturing method based on the present disclosure will now be described.

### Thinning

To manufacture chips based on the present embodiment, by using any of the processing apparatuses 1A to 1D’, thinning is performed, in which, specifically, a front face Pa of a workpiece, i.e. a package substrate P, is thinned to a desired thickness. The thinning, for example, can be performed by the processing apparatus 1A of Embodiment 1 illustrated in FIGS. 1 and 2, and a grinding unit, a turning unit, or the like, is selected for the first processing head 10A, so as to thin the package substrate P. It is also possible to use the processing apparatus 1C of Embodiment 3 illustrated in FIG. 5, for example. In this case, a grinding unit is selected for the first processing head 10A so as to grind the front face Pa of the package substrate P, then a polishing unit is selected for the second processing head 10B so as to polish the front face Pa of the package substrate P to reach a desired thickness.

### Dividing

Once the thinning is performed as mentioned above, dividing is performed to divide the package substrate P into individual device chips. The dividing is performed after the package substrate P, which was processed to a desired thickness in the thinning, is conveyed to a known cutting apparatus (not illustrated). The cutting apparatus includes, for example, a cutting blade that includes an annular cutting blade attached to the tip of the rotation shaft; and a chuck table which is configured to suction-hold the package substrate P and is movable in the processing feed direction. To perform the dividing, the thinned package substrate P, conveyed to the cutting apparatus, is placed and suction-held on the chuck table. Then the cutting blade is rotated at high-speed, and the package substrate P is slit by the cutting blade, and is fed along the division lines demarcating the devices on the package substrate P, whereby the package substrate P is divided into individual chips. Thus the package substrate P is divided into individual chips and desired chips are formed. The method for dividing the package substrate P into individual chips is not limited to using the cutting apparatus in which the cutting blade performs cutting processing. For example, a laser beam having an absorption wavelength for the material of the package substrate P may be applied to the package substrate P along the division lines to perform ablation processing, whereby the package substrate P is divided into individual chips.

In each of the embodiments described above, creep feed grinding is performed on the package substrate P without rotating the chuck table, but the present disclosure is not limited to this processing example. The rotational table may include a rotational driving unit so that the chuck table is rotatable. In this case, the chuck table, which suction-holds the workpiece, is positioned directly under the grinding wheel and is rotated, whereby in-feed grinding is performed on the workpiece.

An inclination adjustment mechanism (not illustrated) may be disposed in at least each holding table or each processing head, so as to reduce thickness irregularity when the upper face of the workpiece is processed, or to process a curved workpiece to be flat. In the case of using the inclination adjustment mechanism for each holding table, a mechanism disclosed in JP 2021-122881 A, for example, may be used. In the case of using the inclination adjustment mechanism for each processing head, a mechanism disclosed in JP 2016-132071 A, for example, may be used.

In the above mentioned chip manufacturing method, the thinning is performed using the processing apparatus configured based on the present disclosure (e.g. processing apparatuses 1A to 1D’), hence productivity to thin the package substrate P excels, and the installation space of the processing apparatus, to perform the thinning, can be conserved. As a result, productivity to manufacture chips from the package substrate P improves. Further, the space to install the apparatuses to perform the thinning and the dividing can be decreased, that is, a chip manufacturing method, that excels in space conservation, is implemented

### REFERENCE SIGNS LIST

1A, 1B, 1C, 1D, 1D’ Processing apparatus

1Aa, 1Aa’ Base

1Ab, 1Ab’ Vertical wall portion

1Ac Upper face

1Ad Guide rail

2A, 2B First workpiece holder

2Aa, 2Ba Moving base

2Ab, 2Bb Moving base

21A, 21B Holding table

22A, 22B Chuck table

3A, 3B First stage drive

4A, 4B Second workpiece holder

41A, 41B Holding table

42A, 42B Chuck table

5A, 5B Second stage drive

6A, 6B Drain pan

7A, 7B First elevating stage

8D Third workpiece holder

9D Fourth workpiece holder

10A First processing head

11A Grinding wheel

12A Grinding stone

13A Rotation shaft

14A Electric motor

15A Support portion

16A Moving base

10B Second processing head

11B Grinding wheel

12B Grinding stone

13B Rotation shaft

14B Electric motor

10C Third processing head

10D Fourth processing head

100 Column

102 Side face

104 Guide rail

106 Ball screw

108 Pulse motor

112 Guide rail

114 Ball screw

116 Pulse motor

130 First conveyor

132 First conveying arm

134 Suction pad

136 Moving base

140 Second conveyor

142 Second conveying arm

144 suction pad

D1 First direction

D2 Second direction

P Package substrate

Pa Front face

R1 First processing region

R2 Load/unload region

R3 Second processing region

R4 Third processing region

R5 Fourth processing region

R6 Load/unload region

S1 First placing stage

S2 Second placing stage

What is claimed is:

1. A processing apparatus, comprising:
a first workpiece holder that holds a workpiece;
a first stage drive that moves the first workpiece holder in a first direction which crosses a vertical direction;
a second workpiece holder that is disposed to be adjacent to the first workpiece holder and holds a workpiece;
a second stage drive that moves the second workpiece holder in the first direction;
a first processing head that processes workpieces held by the first workpiece holder and the second workpiece holder; and
a first elevating stage that moves the first processing head in the vertical direction, so as to move the first processing head to a first processing region in which workpieces held by the first workpiece holder and the second workpiece holder are processed, wherein
the first workpiece holder and the second workpiece holder are configured to be movable to the first processing region in the first direction, independently from each other.

2. The processing apparatus of claim 1, further comprising:
a second processing head that processes workpieces held by the first workpiece holder and the second workpiece holder; and
a second elevating stage that moves the second processing head in the vertical direction, so as to move the second processing head to a second processing region in which the workpieces held by the first workpiece holder and the second workpiece holder are processed.

3. The processing apparatus of claim 1, further comprising:
a third workpiece holder that holds a workpiece;
a third stage drive that moves the third workpiece holder in the first direction;
a fourth workpiece holder that is disposed to be adjacent to the third workpiece holder and holds a workpiece;
a fourth stage drive that moves the fourth workpiece holder in the first direction;
a third processing head that is disposed aligned with the first processing head side-by-side, and processes workpieces held by the third workpiece holder and the fourth workpiece holder; and
a third elevating stage that moves the third processing head in the vertical direction, so as to move the third processing head to a third processing region in which workpieces held by the third workpiece holder and the fourth workpiece holder are processed.

4. The processing apparatus of claim 3, further comprising:
a fourth processing head that processes workpieces held by the third workpiece holder and the fourth workpiece holder; and
a fourth elevating stage that moves the fourth processing head in the vertical direction, so as to move the fourth processing head to a fourth processing region in which workpieces held by the third workpiece holder and the fourth workpiece holder are processed.

5. The processing apparatus of claim 4, wherein
the first workpiece holder and the second workpiece holder are disposed to be aligned vertically, and
the third workpiece holder and the fourth workpiece holder are disposed to be aligned vertically.

6. The processing apparatus of claim 1, wherein
the first workpiece holder and the second workpiece holder are disposed to be aligned vertically.

7. The processing apparatus of claim 1, further comprising:
a first placing stage on which a workpiece is placed; and
a first conveyor that includes a first conveying arm that holds a workpiece, and conveys the workpiece among the first placing stage, the first workpiece holder and the second workpiece holder.

8. The processing apparatus of claim 7, further comprising:
a second placing stage on which a workpiece is placed; and
a second conveyor that includes a second conveying arm that holds a workpiece, and conveys the workpiece among the second placing stage, the first workpiece holder and the second workpiece holder.

9. The processing apparatus of claim 8, wherein
the first conveying arm and the second conveying arm are disposed to be aligned vertically.

10. The processing apparatus of claim 2, further comprising:
a third workpiece holder that holds a workpiece;
a third stage drive that moves the third workpiece holder in the first direction;
a fourth workpiece holder that is disposed to be adjacent to the third workpiece holder and holds a workpiece;
a fourth stage drive that moves the fourth workpiece holder in the first direction;
a third processing head that is disposed aligned with the first processing head side-by-side, and processes workpieces held by the third workpiece holder and the fourth workpiece holder; and
a third elevating stage that moves the third processing head in the vertical direction, so as to move the third processing head to a third processing region in which workpieces held by the third workpiece holder and the fourth workpiece holder are processed.

11. The processing apparatus of claim 10, further comprising:
a fourth processing head that processes workpieces held by the third workpiece holder and the fourth workpiece holder; and
a fourth elevating stage that moves the fourth processing head in the vertical direction, so as to move the fourth processing head to a fourth processing region in which workpieces held by the third workpiece holder and the fourth workpiece holder are processed.

12. The processing apparatus of claim 11, wherein
the first workpiece holder and the second workpiece holder are disposed to be aligned vertically, and
the third workpiece holder and the fourth workpiece holder are disposed to be aligned vertically.

13. The processing apparatus of claim 2, wherein
the first workpiece holder and the second workpiece holder are disposed to be aligned vertically.

14. The processing apparatus of claim 2, further comprising:
a first placing stage on which a workpiece is placed; and
a first conveyor that includes a first conveying arm that holds a workpiece, and conveys the workpiece among the first placing stage, the first workpiece holder and the second workpiece holder.

15. The processing apparatus of claim 14, further comprising:
a second placing stage on which a workpiece is placed; and
a second conveyor that includes a second conveying arm that holds a workpiece, and conveys the workpiece among the second placing stage, the first workpiece holder and the second workpiece holder.

16. The processing apparatus of claim 15, wherein
the first conveying arm and the second conveying arm are disposed to be aligned vertically.

17. A chip manufacturing method, comprising:
thinning a workpiece by using the processing apparatus of claim 1; and
dividing the workpiece after the thinning, so as to generate chips.
